(19) United States
(12) Patent Application Publication
(10) Pub. No.: US 2020/0198285 A1
(43) Pub. Date: Jun. 25, 2020

(54) FEXIBLE SUBSTRATE AND METHOD FOR FABRICATING SAME

(71) Applicant: WUHAN CHINA STAR OPTOELECTRONICS SEMICONDUCTOR DISPLAY TECHNOLOGY CO., LTD., Wuhan, Hubei (CN)

(72) Inventor: Fuyang ZHANG, Wuhan,Hubei (CN)

(21) Appl. No.: 16/485,177

(22) PCT Filed: Jun. 14, 2019
(86) PCT No.: PCT/CN2019/091276

§ 371 Date: Aug. 12, 2019

(30) Foreign Application Priority Data
Dec. 19, 2018 (CN) 201811554499.5

(51) Int. Cl. B32B 3/30; B32B 9/04; B32B 37/24; B32B 38/10; C23C 16/40; C23C 16/50

(52) U.S. Cl. CPC B32B 3/30; B32B 9/045; B32B 37/24; B32B 38/10; C23C 16/401; C23C 16/50; B32B 2457/20; B32B 2255/20; B32B 2307/546; B32B 2037/243; B32B 2037/246; B32B 2307/7244; B32B 2307/7246; B32B 2255/26

(57) ABSTRACT

The present application provides a flexible substrate and a fabricating method thereof. The present application has the advantages that the inorganic protrusions are embedded in the bottom portion of the second polymer layer, which can improve the adhesion between the second polymer layer (organic) material and the inorganic material, and effectively prevent delamination of the second polymer layer and the inorganic layer in sequential processes for fabricating devices such as display panels or during usages of devices such as display panels. The inorganic layer can effectively block water and oxygen from entering the intermediate layer of the substrate, thereby improving reliability of devices such as display panels.

### FIELD OF INVENTION

The present application relates to the, field of display devices, and more particularly to a flexible substrate and a method for fabricating the same.

### BACKGROUND

In recent years, the flexibility of display panels has risen to become a technological innovation pursued by major mobile phone and display panel manufacturers. Panels that are bendable, foldable, rollable, and even arbitrarily deformable are gradually changing from concept to reality. Unlike conventional rigid panels, flexible panels require a flexible substrate to achieve flexibility, foldability, and rollable properties. At present, the more mature technology is to make flexible substrates from materials such as polymers, metal films, cardboards, etc., and the polymer materials are favored for their high flatness and good plasticity.

### TECHNICAL PROBLEM

Due to high moisture permeability and poor high-temperature resistance of polymer materials, it is generally required to use two layers of polymers at the same time and inorganic materials (such as SiO2, SiNx, etc.) in the middle thereof to function as a moisture and oxygen barrier layer while using polymer as the substrate of the display panel. However, due to the poor adhesion between the polymer material and the inorganic material, it is easy to cause the delamination of the upper polymer material and the inorganic material during the subsequent fabrication of the display panel or usages of the display pane, thereby resulting in damage of the display panel.

### SOLUTION TO PROBLEM

The technical problem to be solved by the present application is to provide a flexible substrate and a fabrication method thereof, which can improve the adhesion between the second polymer layer (organic) material and the inorganic material, and effectively prevent delamination of the second polymer layer and the inorganic layer in sequential processes for fabricating devices such as display panels or during usages of devices such as display panels.

In order to solve the above problems, the present application provides a flexible substrate, comprising a first polymer layer, an inorganic layer, and a second polymer layer, wherein the inorganic layer covers the first polymer layer, the second polymer layer cover the inorganic layer, a surface of the inorganic layer facing the second polymer layer comprises a plurality of inorganic protrusions, and the plurality of inorganic protrusions are embedded in the bottom portion of the second polymer layer; the first polymer layer has a thickness of 5-15 μm, the second polymer layer has a thickness of 5-15 μm, the inorganic layer has a thickness of 50-1000 nm, and the plurality of inorganic protrusions have a thickness of 50-1000 nm; the flexible substrate comprises a central region and a periphery region surrounding the central region, and the plurality of inorganic protrusions are disposed over the surface of the inorganic layer facing the second polymer layer in the central region; and at least one of the inorganic protrusions is disposed over the surface of the inorganic layer facing the second polymer layer in the periphery region, and the inorganic protrusion forms a ring structure in the periphery region, and the plurality of the inorganic protrusions in the central region are formed inside the ring structure.

In one embodiment, a pitch between the inorganic protrusions in the central region is less than or equals to 4 mm.

In one embodiment, the thickness of the plurality of inorganic protrusions is less than the thickness of the inorganic layer.

In order to solve the above problems, the present application further provides a flexible substrate, comprising a first polymer layer, an inorganic layer, and a second polymer layer, wherein the inorganic layer covers the first polymer layer, the second polymer layer cover the inorganic layer, and a surface of the inorganic layer facing the second polymer layer comprises a plurality of inorganic protrusions; and the plurality of inorganic protrusions are embedded in the bottom portion of the second polymer layer.

In one embodiment, the flexible substrate comprises a central region and a periphery region surrounding the central region, and the surface of the inorganic layer facing the second polymer layer in the central region and the periphery region both comprises at least inorganic protrusion.

In one embodiment, the inorganic protrusion forms a ring structure in the periphery region, and the plurality of the inorganic protrusions in the central region are formed inside the ring structure.

In one embodiment, a plurality of the inorganic protrusions are disposed in the central region, and the plurality of inorganic protrusions are arranged in an array.

In one embodiment, a pitch between the inorganic protrusions in the central region is less than or equals to 4 mm.

In one embodiment, the thickness of the inorganic protrusions is less than the thickness of the inorganic layer.

In one embodiment, the first polymer layer has a thickness of 5-15 μm, the second polymer layer has a thickness of 5-15 μm, the inorganic layer has a thickness of 50-1000 nm, and the plurality of inorganic protrusions have a thickness of 50-1000 nm.

The present application further provides a method for fabricating the above flexible substrate, comprising the following steps: providing a supporting substrate; forming a first polymer layer over the supporting substrate; forming an inorganic layer over the first polymer layer; forming a plurality of inorganic protrusions over a surface of the inorganic layer; covering the inorganic protrusions and the surface of the inorganic layer with a second polymer layer; and removing the supporting substrate to form the flexible substrate.

In one embodiment, forming the plurality of inorganic protrusions over the surface of the inorganic layer comprises: forming an inorganic material layer over the inorganic layer; and patterning the inorganic material layer to form the plurality of inorganic protrusions.

In one embodiment, forming the plurality of inorganic protrusions over the surface the inorganic layer comprises patterning the inorganic layer to form the plurality of inorganic protrusions over the inorganic layer.

### ADVANTAGEOUS EFFECTS

The present application has the advantages that the inorganic protrusions are embedded in the bottom portion of the second polymer layer, which can improve the adhesion between the second polymer layer (organic) material and the inorganic material, and effectively prevent delamination of the second polymer layer and the inorganic layer in sequential processes for fabricating devices such as display panels or during usages of devices such as display panels. The inorganic layer can effectively block water and oxygen from entering the intermediate layer of the substrate, thereby improving reliability of devices such as display panels.

### BRIEF DESCRIPTION OF DRAWINGS

FIG. 1 is a schematic diagram showing a side view of the structure of a flexible substrate of the present application;

FIG. 2 is a schematic diagram showing a top view of the inorganic protrusions and the inorganic layer; and

FIGS. 3A-3F are flowcharts showing an embodiment of a method for fabricating a flexible substrate of the present application.

### DETAILED DESCRIPTION

The flexible substrate and the fabrication thereof according to the present application will be further described in detail below with reference to the accompanying drawings and embodiments.

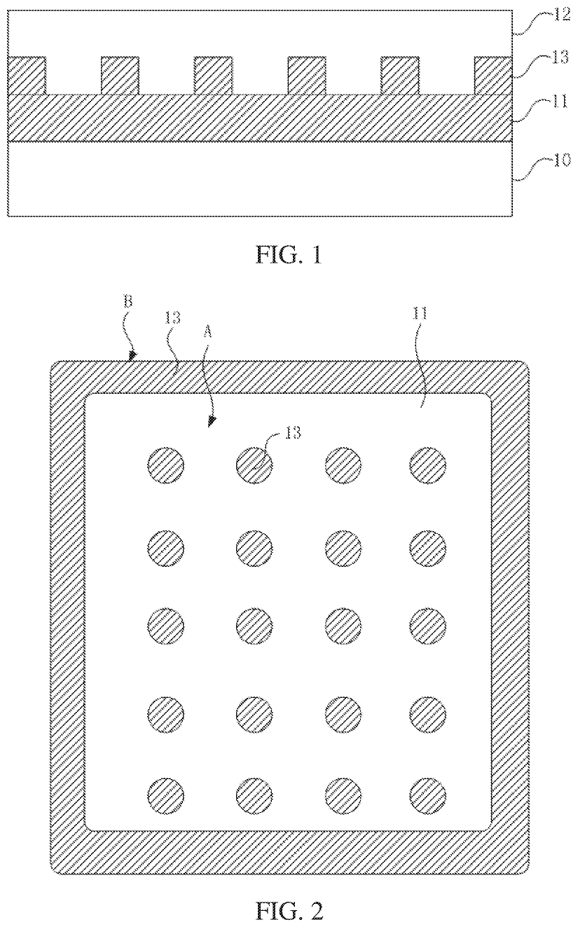

Referring to FIG. 1, an embodiment of the present application provides a polyimide (PI) substrate, comprising a glass substrate.

FIG. 1 is a schematic diagram showing a side view of the structure of a flexible substrate of the present application. Referring to FIG. 1, the flexible substrate of the present application comprises a first polymer layer 10, an inorganic layer 11, and a second polymer layer 12. The inorganic layer 11 covers the first polymer layer 10, and the second polymer layer 12 covers the inorganic layer 11.

The first polymer layer 11 is a flexible layer, and materials for fabricating the first polymer layer 10 comprises one of the plurality of polyimide (PI), Poly-thylenimine (PEI), Polyphenylene sulfide (PPS), and aromatic polyester (PAR), or combinations thereof, but are not limited thereto. In this embodiment, the first polymer layer has a thickness of 5-15 μm. In other embodiments, the thickness of the first polymer layer 10 can be selected according to actual design.

The materials of the inorganic layer can be conventional inorganic materials, and may comprise silicon nitride (SiNx), silicon oxide (SiO2), and amorphous silicon (a-Si) but are limited thereto. The inorganic layer 11 may have a thickness of 50-1000 nm, and the thickness of the inorganic layer 11 may be selected according to actual design. For example, in this embodiment, the inorganic layer 11 has a thickness of 300 nm. In the flexible substrate of the present application, the inorganic layer 11 is capable of effectively blocking moisture and oxygen from entering the flexible substrate.

A surface of the inorganic layer 11 facing the second polymer layer 12 comprises a plurality of inorganic protrusions 13. The materials of the inorganic protrusions 13 may be conventional inorganic materials, and may comprise silicon nitride (SiNx), silicon oxide (SiO2), and amorphous silicon (a-Si) but are limited thereto. The inorganic protrusions 13 has a thickness of 50-1000 nm, and the thickness of the inorganic protrusions 13 may be selected according to actual design. For example, in this embodiment, the thickness of the inorganic protrusions 13 is 300 nm. The material of the inorganic protrusions 13 and the inorganic layer 11 may be the same or different, and the present application is not limited thereto. A plurality of the inorganic protrusions 13 are isolated from each other, and a part of the surface of the inorganic layer 11 is not covered by the inorganic protrusions 13. The thickness of the inorganic protrusions 13 may be equal to or less than the thickness of the inorganic layer 11. In this embodiment, the thickness of the inorganic protrusions 13 may be equal to the thickness of the inorganic layer 11.

The inorganic protrusions 13 are embedded in the bottom of the second polymer layer 12, specifically, the second polymer layer 12 covers the surface of the inorganic protrusions 13 and the exposed surface of the inorganic layer 11. The inorganic protrusions 13 are embedded in the bottom of the second polymer layer 12, which improves the adhesion between the second polymer layer 12 and the inorganic layer 11, and effectively avoids the process of subsequently forming the display panel or the display panel. The separation of the second polymer layer 12 from the inorganic layer 11 occurs during use.

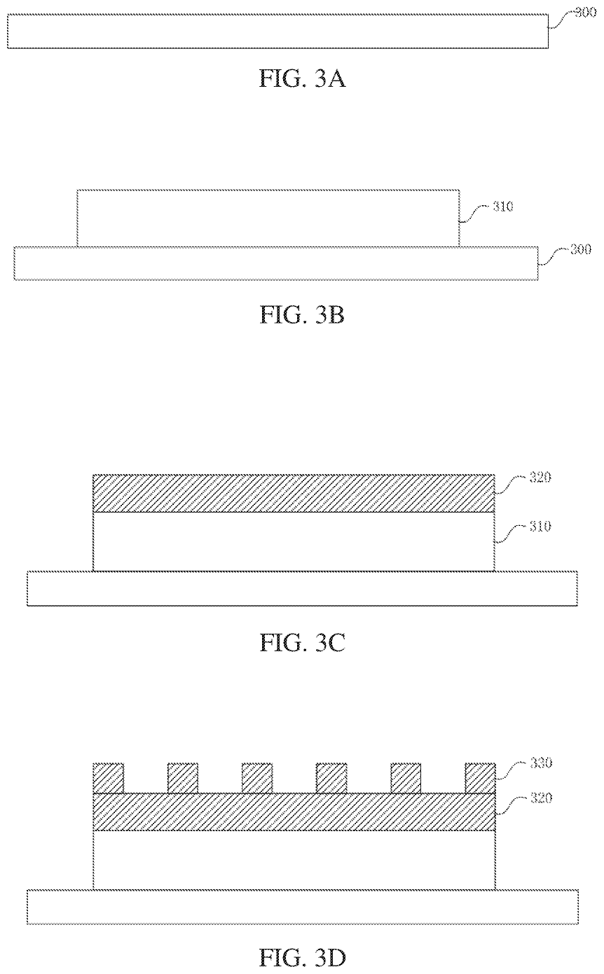

FIG. 2 is a schematic diagram showing a top view of the inorganic protrusions 13 and the inorganic layer 11. Referring to FIGS. 1 and 2, the flexible substrate comprises a central region A and a periphery region B surrounding the central region A. Specifically, if the flexible substrate is used for a display panel, the central region A corresponds to a display region of the display panel, and the periphery region B corresponds to a non-display region of the display panel or a periphery of the display region.

In the central region A and the periphery region B, the surface of the inorganic layer 11 facing the second polymer layer 12 comprises at least one of the inorganic protrusions 13, and the inorganic protrusions 13 are drawn by shadow lines. I Rules for arranging of the inorganic protrusions 13 may be different in the central region A and the periphery region B. For example, in this embodiment, the inorganic protrusion 13 in the periphery region B forms a ring structure surrounding the central region A, and the inorganic protrusion 13 of the central portion A is located inside the ring structure, and the central region A is provided with a plurality of the inorganic protrusions 13, and the plurality of the inorganic protrusions 13 are arranged in an array. The arrangement of the array means that the inorganic protrusions 13 are arranged in an array pattern. Specifically, in this embodiment, a plurality of the inorganic projections 13 are arranged in a straight line in the lateral direction and the longitudinal direction.

The spacing between the inorganic protrusions 13 may be set according to actual conditions. For example, in this embodiment, the spacing between the inorganic protrusions 13 is less than or equal to 4 mm to improve adhesion of the inorganic protrusions 13 and the second polymer layer 12. Further, in one embodiment, the inorganic protrusions 13 in the central region A are cylindrical, and the radius of the inorganic protrusions 13 is less than or equal to 2 mm. The shape of the inorganic protrusions 13 comprises a cylindrical shape, a tapered shape, or the like but is not limited to.

The flexible substrate of the present application utilizes an inorganic layer to effectively^{,} block moisture and oxygen from entering the intermediate layer of the flexible substrate, thereby improving adhesion of the inorganic protrusions 13 and the second polymer layer 12. Further, in one embodiment, in the central region A, the inorganic protrusions 13 are cylindrical, and the radius of the inorganic protrusions 13 is less than or equal to 2 mm. The shape of the inorganic protrusions 13 includes a cylindrical shape, a tapered shape, or the like, but is not limited to.

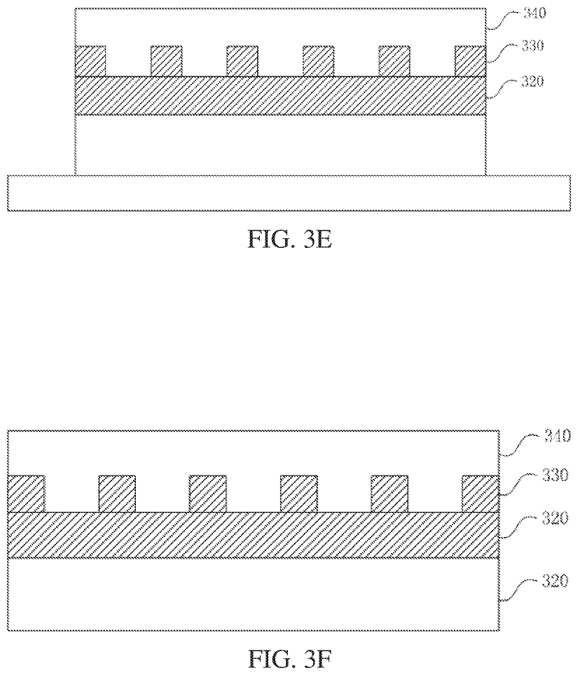

The present applicant also provides a method for fabricating the above flexible substrate. FIG. 3A-3F are flowcharts showing an embodiment of a method for fabricating a flexible substrate of the present application. The fabrication method comprises the following steps.

Referring to FIG. 3A, a supporting substrate 300 is provided. The supporting substrate 300 comprises a conventional structure such as a glass substrate, but is not limited to.

Referring to FIG. 3B, a first polymer layer 310 is formed over the supporting substrate 300. The first polymer layer 310 is a flexible layer, and materials for fabricating the first polymer layer 310 comprise one of polyimide (PI), polyethylemine (PEI), polyphenylene sulfide (PPS), and aromatic polyester (PAR), or a combination thereof. In this embodiment, the material of the first polymer layer 310 is PI. Specifically, a PI layer is coated over the supporting substrate 300 as the first polymer layer 310. The first polymer layer 310 has a thickness of 5-15 μm. For example, the thickness of the first polymer layer 310 is 10 μm.

Referring to FIG. 3C, an inorganic layer 320 is formed on the first polymer layer 310. The material of the inorganic layer 320 may be a conventional inorganic material, and may comprise silicon nitride (SiNx), silicon oxide (SiO2), and amorphous silicon (a-Si) but are limited thereto. Specifically, the inorganic layer 320 is deposited raver the first polymer layer 310 by a method such as vapor deposition. The inorganic layer 320 may have a thickness of 50-1000 nm, and the thickness of the inorganic layer 320 may be selected according to actual design. In this embodiment, SiO2 is used as the inorganic layer 320 by plasm-enhanced chemical vapor deposition (PECVD), and has a thickness of 600 nm.

Referring to FIG. 3D, a plurality of inorganic protrusions 330 are formed over the surface of the inorganic layer 320. The material of the inorganic protrusions 330 may be conventional inorganic materials, and may comprise silicon nitride (SiNx), silicon oxide (SiO2), and amorphous silicon (a-Si) but are limited thereto. The inorganic protrusion 330 may have a thickness of 50-1000 nm, and the thickness of the inorganic protrusion 330 may be selected according to actual design. The material of the inorganic protrusions 330 and the inorganic layer 320 may be the same or different, and the invention is not limited thereto. A plurality of the inorganic protrusions 330 are isolated from each other, and a part of the surface of the inorganic layer 320 is not covered by the inorganic protrusions 330. The thickness of the inorganic protrusions 330 may be equal to or less than the thickness of the inorganic layer 320.

The present application provides two methods of forming the inorganic protrusions 330. Specifically, one method of forming a plurality of inorganic protrusions on the surface of the inorganic layer is to form an inorganic material layer over the surface of the inorganic layer 320, and the inorganic material layer is then patterned to form the inorganic protrusions 330. The other method of forming the plurality of inorganic protrusions 330 over the surface of the inorganic layer 320 is to pattern the inorganic layer 320 to form a plurality of inorganic protrusions 330 over the surface of the inorganic layer 320. Referring to FIG. 3D, in this embodiment, an inorganic material layer is formed over the surface of the inorganic layer 320, and the inorganic material layer is then patterned to form the inorganic protrusions 330. Specifically, an amorphous silicon (a-Si) is formed as an inorganic material layer by PECVD over the inorganic layer 320, and then the inorganic material layer is patterned to form the inorganic protrusions 330.

Referring to FIG. 3E, a surface of the inorganic protrusions 330 and the inorganic layer 320 is covered with a second polymer layer 340. The second polymer layer 340 is a flexible layer, and materials for fabricating the second polymer layer 340 comprise one of polyimide (PI), polyethylenimine (PEI), polyphenylene sulfide (PPS), and aromatic polyester (PAR), or a combination thereof. In this embodiment, the material of the second polymer layer 340 is PI. Specifically, a surface of the inorganic protrusions 330 and the inorganic layer 320 is covered with a PI layer to function as the second polymer layer 340, and the second polymerlayer 340 covers the inorganic protrusions 330. The surface and the exposed surface of the inorganic layer 320 form a structural in which the inorganic protrusions 330 are embedded in the bottom portion of the second polymer layer 340. The second polymer layer 340 has a thickness of 5-15 μm. For example, in this embodiment, the second polymer layer 340 has a thickness of 8 μm.

Referring to FIG. 3F, the supporting substrate 300 is removed to form the flexible substrate comprising the first polymer layer 310, the inorganic layer 320, the inorganic protrusions 330, and the second polymer layer 340. This step is an optional step, and the supporting substrate 300 may be removed after the flexible substrate is bonded to an external member. For example, if the flexible substrate is used as a substrate of a display panel, the supporting substrate 300 may be removed after forming a display panel on the flexible substrate.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

### INDUSTRIAL APPLICABILITY

The subject matter of the present application can be fabricated and used in the industry, thereby having industrial applicability.

1. A flexible substrate, comprising a first polymer layer, an inorganic layer, and a second polymer layer, wherein-the inorganic layer covers the first polymer layer, the second polymer layer cover the inorganic layer, a surface of the inorganic layer facing the second polymer layer comprises a plurality of inorganic protrusions, and the plurality of inorganic protrusions are embedded in the bottom portion of the second polymer layer; the flexible substrate comprises a central region and a periphery region surrounding the central region, and the plurality of inorganic protrusions are disposed over the surface of the inorganic layer facing the second polymer layer in the central region; and at least one of the inorganic protrusions is disposed over the surface of the inorganic layer facing the second polymer layer in the periphery region, and the inorganic protrusion forms a ring structure in the periphery region, and the plurality of the inorganic protrusions in the central region are formed inside the ring structure.

2. The flexible substrate as claimed in claim 1, wherein a pitch between the inorganic protrusions in the central region is less than or equals to 4 mm, and the first polymer layer has a thickness of 5-15 μm, the second polymer layer has a thickness of 5-15 μm, the inorganic layer has a thickness of 50-1000 nm, and the plurality of inorganic protrusions have a thickness of 50-1000 nm.

3. The flexible substrate as claimed in claim 1, wherein the thickness of the plurality of inorganic protrusions is less than the thickness of the inorganic layer.

4. A flexible substrate, comprising a first polymer layer, an inorganic layer, and a second polymer layer, wherein:
the inorganic layer covers the first polymer layer, the second polymer layer cover the inorganic layer, and a surface of the inorganic layer facing the second polymer layer comprises a plurality of inorganic protrusions; and
the plurality of inorganic protrusions are embedded in the bottom portion of the second polymer layer.

5. The flexible substrate as claimed in claim 4, wherein the flexible substrate comprises a central region and a periphery region surrounding the central region, and the surface of the inorganic layer facing the second polymer layer in the central region and the periphery region both comprises at least one inorganic protrusion.

6. The flexible substrate as claimed in claim 5, wherein the inorganic protrusion forms a ring structure in the periphery region, and the plurality of the inorganic protrusions in the central region are formed inside the ring structure.

7. The flexible substrate as claimed in claim 5, wherein a plurality of the inorganic protrusions are disposed in the central region, and the plurality of inorganic protrusions are arranged in an array.

8. The flexible substrate as claimed in claim 7, wherein a pitch between the inorganic protrusions in the central region is less than or equals to 4 mm.

9. The flexible substrate as claimed in claim 4, wherein the thickness of the inorganic protrusions is less than the thickness of the inorganic layer.

10. The flexible substrate as claimed in claim 4, wherein the first polymer layer has a thickness of 5-15 μm, the second polymer layer has a thickness of 5-15 μm, the inorganic layer has a thickness of 50-1000 nm, and the plurality of inorganic protrusions have a thickness of 50-1000 nm.

11. A method for fabricating the flexible substrate as claimed in claim 4, comprising the following steps:
providing a supporting substrate;
forming a first polymer layer over the supporting substrate;
forming an inorganic layer over the first polymer layer;
forming a plurality of inorganic protrusions over a surface of the inorganic layer;
covering the inorganic protrusions and the surface of the inorganic layer with a second polymer layer; and
removing the supporting substrate to form the flexible substrate.

12. The method for fabricating the flexible substrate as claimed in claim 11, wherein forming the plurality of inorganic protrusions over the surface of the inorganic layer comprises;
forming an inorganic material layer over the inorganic layer; and
patterning the inorganic material layer to form the plurality of inorganic protrusions.

13. Original The method for fabricating substrate as claimed in claim 11, wherein forming the plurality of inorganic protrusions over the surface the inorganic layer comprises patterning the inorganic layer to form the plurality of inorganic protrusions over the inorganic layer.
